(19) United States
(12) Patent Application Publication
(10) Pub. No.: US 2008/0093638 A1
(43) Pub. Date: Apr. 24, 2008

(54) Semiconductor Device

(75) Inventor: Shunsuke Kobayashi, Ora-gun (JP)

Correspondence Address: MORRISON & FOERSTER LLP, 1650 TYSONS BOULEVARD, SUITE 400, MCLEAN, VA, 22102, US

(73) Assignees: Sanyo Electric Co., Ltd., Moriguchi-shi (JP); Sanyo Semiconductor Co., Ltd., Ora-gun (JP)

(21) Appl. No.: 11/877,306

(22) Filed: Oct. 23, 2007

(30) Foreign Application Priority Data
Oct. 23, 2006 (JP) 2006-287907

(51) Int. Cl. H01L 27/098

(52) U.S. Cl. 257/275; 257/E27.069

(57) ABSTRACT

In a J-FET for large current use, there has been a limitation on reduction in a chip size or enlargement of the operation regions because two operation regions are arranged in line along a diagonal line of a chip. To eliminate the limitation, in this invention, gate regions are extended in a direction along one of sides of a chip, two operation regions are arranged along a first diagonal line of the chip, and two pad electrodes are arranged along a second diagonal line of the chip. Thus, the area on the chip can be effectively utilized. As a result, a chip size can be reduced with the same operation region area, and the operation region area can be increased with the same chip size.

This application claims priority from Japanese Patent Application Number 2006-287907 filed Oct. 23, 2006, the content of which is incorporated herein by reference in its entirety.

### BACKGROUND OF THE INVENTION

1. Field of the Invention

The present invention relates to a semiconductor device used for a high-frequency device, and more particularly relates to a semiconductor device having improved high-frequency characteristics and a reduced chip size.

2. Description of the Related Art

FIGS. 6 and 7 are views showing an example of a junction FET (hereinafter referred to as a J-FET) used for a high-frequency device.

FIGS. 6A and 6B are plan views showing a J-FET 200. With reference to FIG. 6A, in the J-FET 200, first and second operation regions 35a and 35b and first and second pad electrodes 29p and 30p each connected to both the operation regions 35a and 35b are disposed on a semiconductor substrate 20 constituting a semiconductor chip.

Since the first and second operation regions 35a and 35b have the same configuration, the first operation region 35a will be described below.

FIG. 7 is a cross-sectional view along the line c-c in FIG. 6A, showing an example of the conventional J-FET.

The semiconductor substrate 20 is obtained by forming a p type semiconductor layer 22, for example, by epitaxial growth or the like on a p type silicon semiconductor substrate 21, for example. On a surface of the semiconductor substrate 20, an n type well region 24 is provided by isolating an n type semiconductor layer 24′ with an isolation region 23 that is a high-concentration p type impurity region. The n type well region serves as a channel region, and n+ type source and drain regions are provided, for example, in a stripe pattern in the n type well region. Moreover, between the source and drain regions, gate regions 27 are formed in a stripe pattern.

A source electrode 29 and a drain electrode 30 are disposed so as to overlap with the source and drain regions 25 and 26, respectively, in the first operation region, and are connected to the source and drain regions 25 and 26, respectively, through contact holes provided in an insulating film 40 covering the semiconductor substrate. Thus, the first operation region 35a is formed. This technology is described for instance in Japanese Patent Application Publication No. Hei 8-227900.

With reference to FIGS. 6A and 6B again, a layout on the chip will be described.

The source electrodes 29 in the first and second operation regions 35a and 35b are connected to the first pad electrode (source pad electrode) 29p, and the drain electrodes 30 in the first and second operation regions 35a and 35b are connected to the second pad electrode (drain pad electrode) 30p.

In the conventional layout, as shown in FIG. 6A, the first and second operation regions 35a and 35b are arranged along a first diagonal line d1 of the semiconductor substrate (chip) 20 so as to align end portions of the channel regions 24 with each other. Meanwhile, the gate regions 27, the source regions 25 and the drain regions 26 in the first and second operation regions 35a and 35b are extended along a second diagonal line d2 of the semiconductor substrate (chip). Moreover, the source pad electrode 29p and the drain pad electrode 30p are also disposed along the second diagonal line d2. Specifically, the two operation regions 35a and 35b are arranged so as to align the end portions of the channel regions 24 with a direction of the diagonal line (for example, the first diagonal line d1) of the chip.

On the other hand, FIG. 6B shows a layout in which the first and second operation regions 35a and 35b are disposed so as to be aligned with a side e of the chip.

With a given area of each of the first operation region 35a, the second operation region 35b and the chip, the area on the chip can be utilized more effectively by arranging the two operation regions 35a and 35b along the diagonal line of the chip in the layout shown in FIG. 6A than in the layout shown in FIG. 6B.

A J-FET for high-frequency use with a large current capacity has good strain characteristics but has a problem concerning reduction in a chip size because the J-FET requires securing large operation regions.

As shown in FIGS. 6A and 6B, as constituent components on the chip, the operation regions, the source pad electrode and the drain pad electrode occupy most of the area on the chip. Accordingly, in order to increase the operation regions without increasing the chip size, it is necessary to reduce the size of each of the pad electrodes. However, as to the pad electrodes, a safe pad size required in an assembly step is determined since bonding wires, for example, are fixed to the pad electrodes. Thus, the pad electrodes cannot be set smaller than necessary.

For example, in the conventional layout shown in FIG. 6A, the first and second operation regions 35a and 35b are arranged in line so as to align the end portions of the channel regions 24 with the direction of the first diagonal line d1 of the chip 20. Thus, the area on the chip can be utilized more effectively than in the layout in which the two operation regions 35a and 35b are arranged side by side so as to align the end portions of the channel regions 24 with the side e of the chip, shown in FIG. 6B. However, the length of the chip in the diagonal line direction is required to be equal to or larger than widths of the two operation regions in the diagonal line d1 direction. Thus, there is a limit on enlargement of the operation regions or reduction in the chip size.

Moreover, as a configuration for securing large operation regions while securing a safe pad size, there has been known a structure in which the respective pad electrodes are provided on the operation regions with an insulating film (for example, a nitride film) interposed therebetween. However, there is a problem that cracks are generated in the insulating film by stress in pressure bonding of the bonding wires to cause an operation failure such as short-circuiting.

In addition, there has also been known a structure in which two operation regions are arranged in an L pattern on a chip in such a manner that stripe-shaped gate regions (the same goes for source and drain regions) in the two operation regions are extended in directions different from each other. However, in order to achieve good strain characteristics, it is desirable to have the gate regions extended in the same direction in the two operation regions.

Specifically, it is desired to further improve the strain characteristics by increasing the current capacity of the J-FET. However, on the other hand, it is also necessary to reduce costs by reducing the chip size to improve yield of a wafer. Moreover, reduction in the chip size is also a market demand associated with miniaturization of communication devices and the like in which the J-FET is used. However, the conventional layout has its limits in terms of reduction in the chip size while maintaining a desired current capacity.

### SUMMARY OF THE INVENTION

The invention provides a semiconductor device including a rectangular semiconductor substrate of a first general conductivity type, a first operation region of a second general conductivity type formed in the rectangular substrate and having a plurality of linear impurity regions of the first general conductivity type formed in the first operation region, a second operation region of the second general conductivity type formed in the rectangular substrate having a plurality of linear impurity regions of the first general conductivity type formed in the second operation region, a first electrode pad disposed on the rectangular substrate and connected to the first operation region, and a second electrode pad disposed on the rectangular substrate and connected to the second operation region. The linear impurity regions of the first and second operation regions are arranged parallel to an edge of the rectangular substrate, the first and second operation regions are disposed along a first diagonal of the rectangular substrate so that the first diagonal intersects the first and second operation regions, and the first and second electrode pads are disposed along a second diagonal of the rectangular substrate so that the second diagonal intersects the first and second electrode pads.

The invention also provides a semiconductor device including a rectangular semiconductor substrate of a first general conductivity type, and a first rectangular channel region of a second general conductivity type formed in the rectangular substrate and having a plurality of linear gate regions of the first general conductivity type, a plurality of source regions of the second general conductivity type and a plurality of drain regions of the second general conductivity type formed in the first rectangular channel region. The device also includes a second rectangular channel region of the second general conductivity type formed in the rectangular substrate and having a plurality of linear gate regions of the first general conductivity type, a plurality of source regions of the second general conductivity type and a plurality of drain regions of the second general conductivity type formed in the second rectangular channel region. The device further includes a source electrode pad disposed on the rectangular substrate and connected to the source regions of the first and second rectangular channel regions, and a drain electrode pad disposed on the rectangular substrate and connected to the drain regions of the first and second rectangular channel regions. The linear gate regions of the first and second rectangular channel regions are arranged parallel to an edge of the rectangular substrate, and a longitudinal edge of the first rectangular channel region overlaps partially with a longitudinal edge of the second rectangular channel region.

### BRIEF DESCRIPTION OF THE DRAWINGS

FIG. 1 is a plan view showing a first embodiment of the present invention.

FIG. 2A is a plan view and FIG. 2B is a cross-sectional view showing the first embodiment of the present invention.

FIG. 3 is a plan view showing the first embodiment of the present invention.

FIGS. 4A and 4B are plan views showing a second embodiment of the present invention.

FIG. 5 is a plan view showing the second embodiment of the present invention.

FIGS. 6A and 6B are plan views showing a conventional technology.

FIG. 7 is a cross-sectional view showing the conventional technology.

### DESCRIPTION OF THE EMBODIMENTS

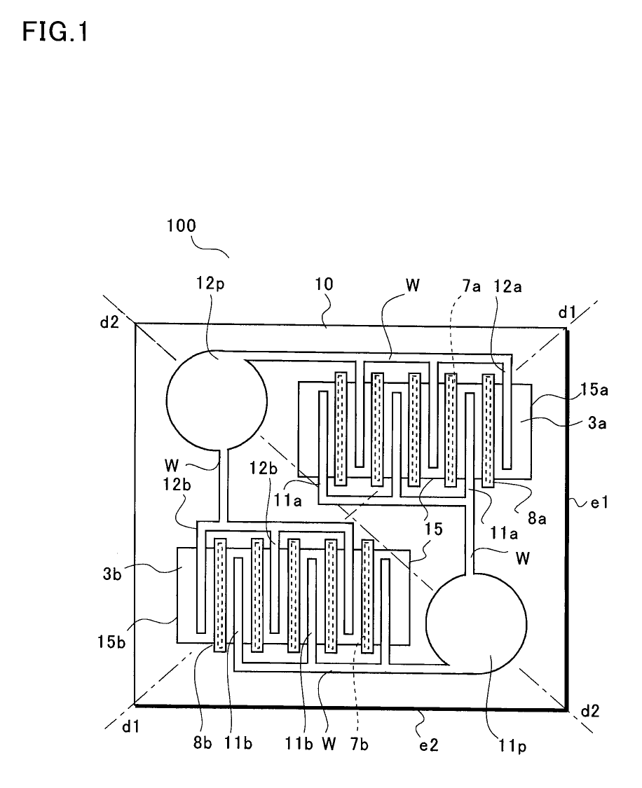

With reference to FIGS. 1 to 5, embodiments of the present invention will be described below. Note that semiconductor devices according to the embodiments of the present invention are suitably used for a junction FET (Field Effect Transistor: hereinafter referred to as a J-FET) which changes a cross-sectional area of a channel by use of depletion layers in one or more pn junctions biased in opposite directions. The J-FET will be described below as an example.

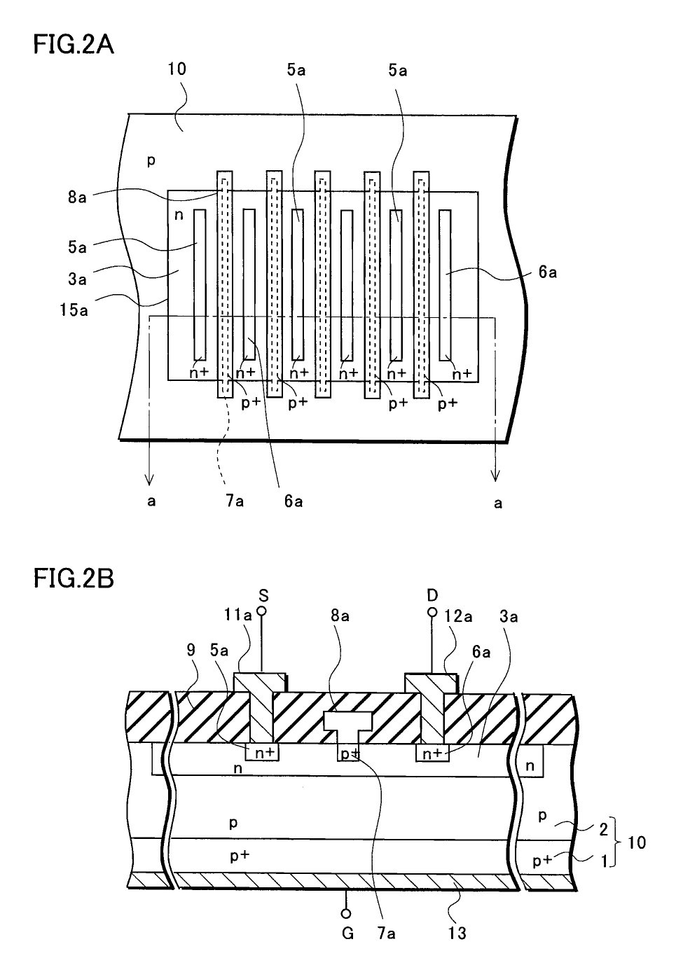

First, with reference to FIGS. 1 and 2, a first embodiment of the present invention will be described.

FIG. 1 is a plan view showing a J-FET of the first embodiment. The J-FET of this embodiment includes a one conductivity type semiconductor substrate, a first operation region, a second operation region, a first pad electrode and a second pad electrode.

In a J-FET 100, two operation regions 15 (a first operation region 15a and a second operation region 15b) are provided on a semiconductor substrate 10 which constitutes one chip. In the first and second operation regions 15a and 15b, source electrodes 11a and 11b and drain electrodes 12a and 12b are provided, which are connected thereto, respectively. The source electrodes 11a and 11b are connected to a first pad electrode (source pad electrode) 11p provided on the semiconductor substrate 10 outside the first and second operation regions 15a and 15b. Moreover, the drain electrodes 12a and 12b are connected to a second pad electrode (drain pad electrode) 12p provided on the semiconductor substrate 10 outside the first and second operation regions 15a and 15b.

With reference to FIGS. 2A and 2B, the operation regions in the J-FET 100 will be described. Note that the first and second operation regions 15a and 15b in this embodiment have the same configuration. Therefore, the first operation region 15a will be described.

FIG. 2A is a plan view showing the first operation region 15a and FIG. 2B is a partial cross-sectional view along the line a-a in FIG. 2A. Note that an insulating film on a surface of the substrate and metal electrodes (a source electrode and a drain electrode) are omitted in FIG. 2A. Moreover, FIG. 2B shows one cell represented by a set of source, drain and gate regions.

With reference to FIG. 2A, the first operation region 15a is provided on the surface of the p type semiconductor substrate 10. Here, the first operation region 15a in this embodiment is a collective term for regions in which a channel region 3a, source regions 5a, drain regions 6a, gate regions 7a and the source and drain electrodes 11a and 12a (see FIG. 1) are provided. Moreover, the first operation region 15a has the same area as that of the channel region 3a.

Similarly, the second operation region 15b is a collective term for regions in which a channel region 3b, source regions 5b, drain regions 6b, gate regions 7b and the source and drain electrodes 11b and 12b (see FIG. 1) are provided. Moreover, the second operation region 15b has the same area as that of the channel region 3b.

In a surface of a p type semiconductor substrate 10, an n type channel region 3a is provided. In a surface of the channel region 3a, p type gate regions (broken lines) 7a and n type source and drain regions 5a and 6a are provided in a stripe pattern. Moreover, conductive layers 8a are provided on the gate regions 7a so as to overlap therewith, and the conductive layers 8a and the gate regions 7a come into contact with each other.

With reference to FIG. 2B, the p type semiconductor substrate 10 is obtained by forming a p type semiconductor layer 2, for example, by epitaxial growth or the like on a p type silicon semiconductor substrate (hereinafter referred to as a p+ type semiconductor substrate) 1. The p type semiconductor layer 2 has an impurity concentration of, for example, about 1.46E16 cm⁻³. The channel region 3a is an island-pattern impurity region formed by selectively ion-implanting and diffusing n type impurities into a surface of the p type semiconductor layer 2. The channel region 3a has an impurity concentration of, for example, about 4.5E16 cm⁻³. The n type channel region 3a forms pn junctions with the p type semiconductor layer 2 on its side faces and bottom face.

It is noted that conductivity types such as n+, n and n− belong in a general conductivity type, and conductivity types such as p+, p and p− belong in another general conductivity type.

The source and drain regions 5a and 6a are regions formed by implanting and diffusing n type impurities into the surface of the channel region 3a. An insulating film 9 is provided on the surface of the substrate 10, and the source and drain electrodes 11a and 12a in a stripe pattern are provided so as to overlap with the source and drain regions 5a and 6a (see FIG. 1). The source and drain electrodes 11a and 12a come into contact with the source and drain regions 5a and 6a, respectively, through contact holes provided in the insulating film 9.

The gate region 7a is a p type impurity diffusion region provided between the source and drain regions 5a and 6a in the channel region 3a. It is preferable that the gate region 7a has an impurity concentration of about 1E18 cm⁻³. Moreover, a depth of the gate region 7a is set the same as those of the source and drain regions 5a and 6a.

One cell includes a set of the source region 5a (the source electrode 11a), the drain region 6a (the drain electrode 12a) and the gate region 7a shown in FIG. 2B. As shown in FIG. 2A, a plurality of cells are arranged in one channel region 3a to form the first operation region 15a.

The gate region 7a comes into contact with the conductive layer 8a provided thereon. The conductive layer 8a is a polysilicon layer containing p type impurities and can reduce a gate resistance. The gate resistance becomes an input resistance and significantly affects noise and strain characteristics. However, according to this embodiment, the gate resistance can be reduced by the conductive layer 8a. Thus, the noise and strain characteristics can be improved.

The conductive layer 8a is extended to the surface of the p type semiconductor layer 2 outside the channel region 3a (see FIG. 2A). Moreover, a gate electrode 13 is provided on a back surface of the p+ type semiconductor substrate 1. The gate region 7a is electrically connected to the gate electrode 13 through the conductive layer 8a, the p type semiconductor layer 2 and the p+ type semiconductor substrate 1.

In this embodiment, the channel region 3a is formed in an island pattern in the surface of the p type semiconductor layer 2 by ion implantation and diffusion. Specifically, it is possible to form the channel region 3a having a small depth from the surface of the p type semiconductor layer 2. Moreover, high-frequency characteristics of the J-FET 100 are affected by a gate junction capacitance that is a sum of a gate-source junction capacitance C_{GS} and a gate-drain junction capacitance C_{GD}.

The source and drain regions 5a and 6a of the same conductivity type are provided in the channel region 3a, and the channel region 3a is connected thereto. Moreover, the p type semiconductor layer 2 and the p+ type semiconductor substrate 1 are electrically connected to the gate region 7a through the conductive layer 8a. Specifically, a pn junction capacitance between the gate region 7a (the semiconductor layer 2) and the channel region 3a can be reduced by the shallow channel region 3a formed by ion implantation. Moreover, reduction in the pn junction capacitance leads to reduction in the gate-source junction capacitance C_{GS} and the gate-drain junction capacitance C_{GD}. Consequently, a cutoff frequency f_{T} can be improved by reducing the combined capacitance (gate capacitance C_{G}).

Moreover, end portions (the side faces and bottom face) of the channel region 3a form pn junctions with the p type semiconductor layer 2. Specifically, since there is a relatively small difference in impurity concentration between the pn junctions on the side faces of the channel region 3a, the pn junction capacitance can be reduced. Thus, leak currents I_{GSS} on the side faces of the channel region 3a can be reduced.

Furthermore, by shallowly forming the gate region 7a, a signal path from the source region 5a through below the gate region 7a to the drain region 6a in the J-FET 100 can be shortened compared with that in the case where the gate region 7a is deep. Accordingly, an internal resistance can be reduced by the shortened signal path.

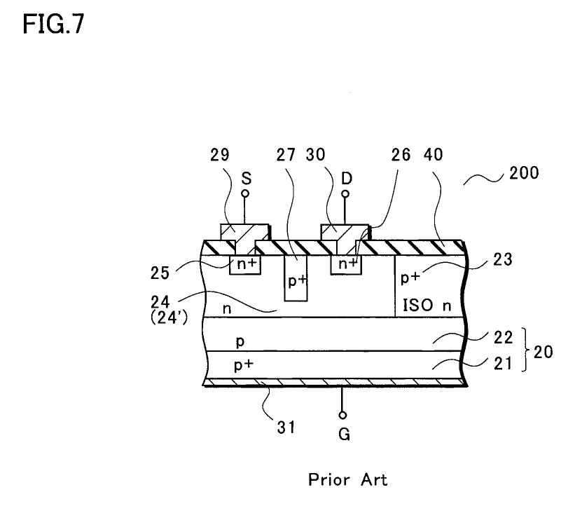

Note that the configuration of the first operation region 15a described above is an example. The first operation region may have a configuration in which the n type semiconductor layer 24′ is provided on the p type semiconductor layer 22 and the channel region 24 is isolated by the isolation region 23 that is the high-concentration impurity region, for example, as in the case of the conventional structure shown in FIG. 7.

In this embodiment, the first and second operation regions 15a and 15b have approximately the same configuration in which conditions such as sizes of the respective regions and the impurity concentrations are set the same. In other words, the first and second operation regions 15a and 15b having the same characteristics are arranged on one semiconductor substrate (chip) 10.

With reference to FIG. 1 again, a layout on the semiconductor substrate 10 will be described.

In the respective first and second operation regions 15a and 15b, the source electrodes 11a and 11b and the drain electrodes 12a and 12b, which are connected to the source and drain regions (not shown here) while overlapping therewith, are provided on the channel regions 3a and 3b. The source electrodes 11a and 11b and the drain electrodes 12a and 12b are formed in a stripe pattern but are bundled by wirings W, respectively, outside the respective operation regions 15 so as to have a comb-teeth shape. The source electrode 11b and the drain electrode 12b are disposed in a state where the respective comb teeth are engaged with each other.

The source electrode 11a in the first operation region 15a and the source electrode 11b in the second operation region 15b are connected to the first pad electrode (source pad electrode) 11p by the wirings W. The drain electrode 12a in the first operation region 15a and the drain electrode 12b in the second operation region 15b are connected to the second pad electrode (drain pad electrode) 12p by the wirings W. Thus, the source pad electrode 11p is common-connected to the source regions in the first and second operation regions 15a and 15b. Moreover, the drain pad electrode 12p is common-connected to the drain regions in the first and second operation regions 15a and 15b.

The gate regions 7a in the first operation region 15a are connected to the gate electrode (not shown) provided on the back surface of the p type semiconductor substrate 10 through the conductive layers 8a and the p type semiconductor substrate 10. Moreover, the gate regions 7b in the second operation region 15b are also connected to the gate electrode (not shown) provided on the back surface of the p type semiconductor substrate 10 through the conductive layers 8b and the p type semiconductor substrate 10.

In this embodiment, the gate regions 7a in the first operation region 15a are extended along a first side e1 of the semiconductor substrate 10. Moreover, the gate regions 7b in the second operation region 15b are also extended along the first side e1 of the semiconductor substrate 10.

In the two operation regions 15, the source and drain regions (not shown here) are also disposed parallel to the gate regions 7a and 7b, in other words, extended in a direction along the first side e1. Moreover, the source electrodes 11a and 11b and the drain electrodes 12a and 12b, which come into contact with the source and drain regions while overlapping therewith, are also extended in the direction along the first side e1.

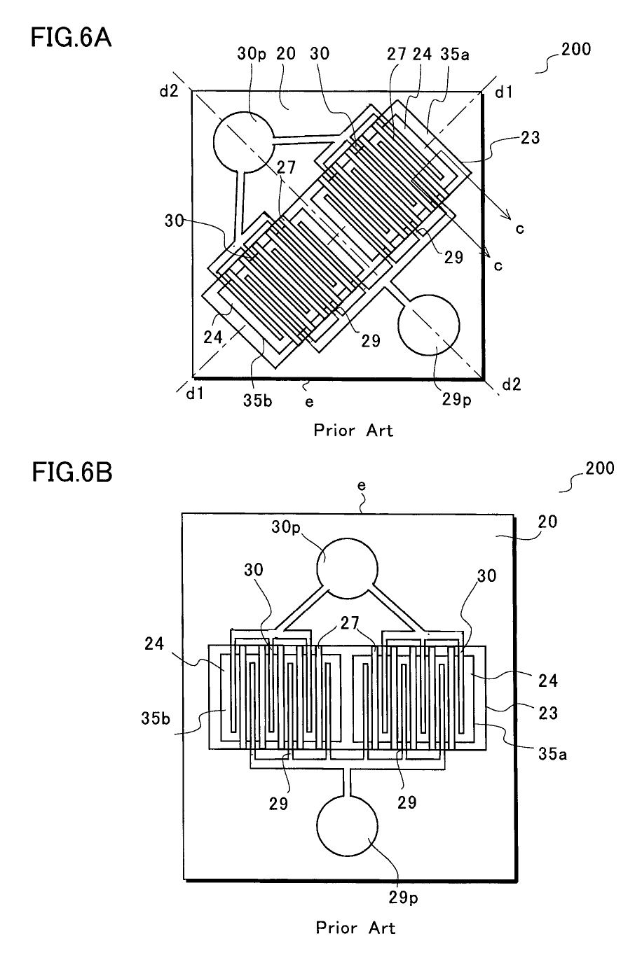

Moreover, the first and second operation regions 15a and 15b are disposed so as to be lined up along a first diagonal line d1 of the semiconductor substrate 10 as indicated by a dashed line. Note, however, that the first and second operation regions 15a and 15b are not arranged along the first diagonal line d1 so as to align the end portions of the channel regions 3a and 3b with each other (see FIG. 6A). Since the gate regions 7a and 7b are extended along the first side e1 of the semiconductor substrate 10, the first and second operation regions 15a and 15b are arranged along the first diagonal line d1 in a step-like pattern.

Furthermore, the source pad electrode 11p and the drain pad electrode 12p are arranged along a second diagonal line d2 of the semiconductor substrate 10.

As described above, in this embodiment, both of the gate regions 7a and 7b in the first and second operation regions 15a and 15b are extended along the first side e1 of the semiconductor substrate 10, and the source pad electrode 11p and the first operation region 15a are arranged along the first side e1. Moreover, along a second side e2 of the semiconductor substrate 10, the second side being extended in a direction different from that of the first side e1, the second operation region 15b and the source pad electrode 11p are arranged.

Note that, although not shown in the drawings, arrangement positions of the first and second operation regions 15a and 15b and those of the source pad electrode 11p and the drain pad electrode 12p may be replaced with each other, respectively. Furthermore, the respective pad electrodes 11p and 12p may be arranged along the first diagonal line d1 and the two operation regions 15 may be arranged along the second diagonal line d2.

Moreover, this embodiment is not limited to the layout in which the two operation regions 15 and the two pad electrodes 11p and 12p are disposed immediately above the first and second diagonal lines d1 and d2.

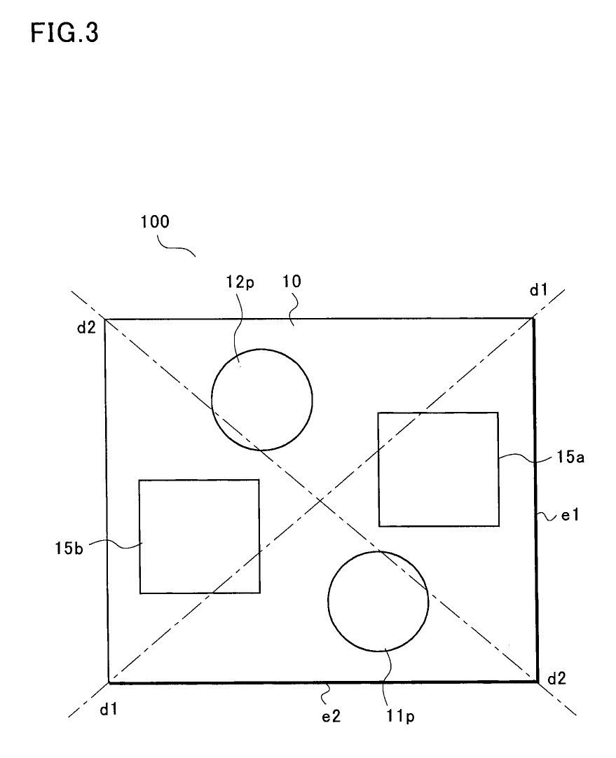

FIG. 3 is a view showing another layout example different from that shown in FIG. 1. FIG. 3 shows only contours of the first operation region 15a, the second operation region 15b, the first pad electrode 11p and the second pad electrode 12p.

As shown in FIG. 3, as long as the first operation region 15a, the second operation region 15b, the first pad electrode 11p and the second pad electrode 12p are arranged along the first and second diagonal lines d1 and d2, a layout in which the operation regions and the pad electrodes are disposed at positions parallel shifted from the positions immediately above the first and second diagonal lines d1 and d2 may be adopted.

As described above, according to this embodiment, a space on the semiconductor substrate 10 can be effectively utilized by arranging the first and second operation regions 15a and 15b along the diagonal line of the chip so as to align corners of the respective operation regions with corners of the semiconductor substrate (chip) 10.

In the conventional layout shown in FIG. 6A, an area on the chip is effectively utilized compared with FIG. 6B. However, it is necessary to secure a length equal to lengths (widths) of the two operation regions, the first and second operation regions 15a and 15b, as the length of the diagonal line (for example, the first diagonal line d1) of the chip. Specifically, when the widths of the operation regions are set larger than the first and second operation regions 35a and 35b shown in FIG. 6A, the length of the diagonal line is also increased and the chip size is increased after all.

Consequently, as in this embodiment, the direction of the gate regions 7a and 7b is set along the first side e1 and the first and second operation regions 15a and 15b are disposed while partially overlapping with each other in the direction of the second side e2 so as to be arranged in the step-like pattern along the first diagonal line d1. Thus, for example, the length of the first diagonal line d1 can be set shorter than that in the case where the first and second operation regions 15a and 15b are arranged as shown in FIG. 6A. As a result, an increase in the chip size can be avoided even if a safe size of each of the pad electrodes 11p and 12p for an assembly step is secured.

Accordingly, the chip size can be reduced while securing the same areas as those in the conventional case for the first and second operation regions 15a and 15b and also securing the safe pad size in the assembly step. More specifically, in the conventional structure shown in FIG. 6A, when the required operation regions (current capacity) are secured, a limit of the chip size is up to 0.5 mm square. Meanwhile, according to this embodiment, the chip size can be reduced to 0.45 mm square with the same operation region area (current capacity). Thus, yield of the chip can be improved to 1.25 times greater than that in the conventional structure.

Moreover, when the same chip size as that in the conventional structure is maintained, the areas of the first and second operation regions 15a and 15b can be increased while securing the safe pad size in the assembly step. Therefore, with the same gate width, the number of stripes of the gate regions 7a and 7b can be increased. Thus, the current capacity can be increased. More specifically, in the case of the same material and process conditions as those in the conventional case, for example, a current capacity of 60 mA can be secured with the chip size of 0.45 mm square in this embodiment. Compared with the conventional case (FIG. 6A) where the current capacity is about 30 mA with the chip size of 0.5 mm square, reduction in the chip size and an increase in the current capacity can be achieved.

As described above, by utilizing the space on the semiconductor substrate 10, the first and second operation regions 15a and 15b and the first and second pad electrodes 11p and 12p can be arranged. As described above, in order to secure sufficient operation regions or to reduce the chip size, there has been known the configuration in which the pad electrodes are disposed on the operation regions with the insulating film interposed therebetween. However, in this embodiment, it is possible to avoid failures such as cracks in the insulating film due to stress in wire bonding and to prevent deterioration of reliability compared with the configuration as described above.

Furthermore, for improvement of strain characteristics, it is desirable to set the gate regions 7a and 7b in the first and second operation regions 15a and 15b to be extended in the same direction. In this embodiment, the gate regions 7a and 7b in the first and second operation regions 15a and 15b can be extended in the same direction (in the extending direction of the first side e1 of the semiconductor substrate 10). This is advantageous for the strain characteristics.

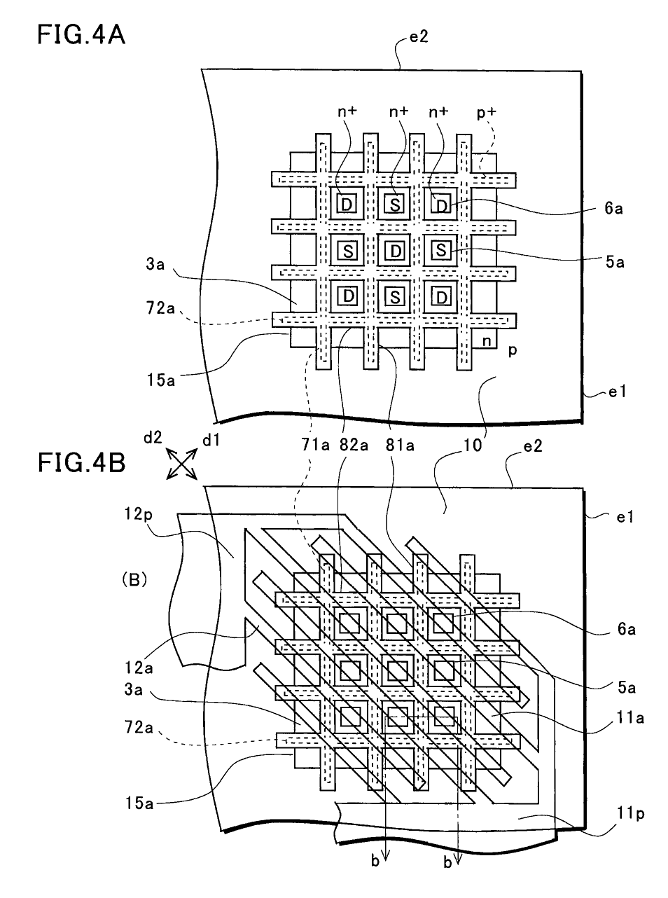

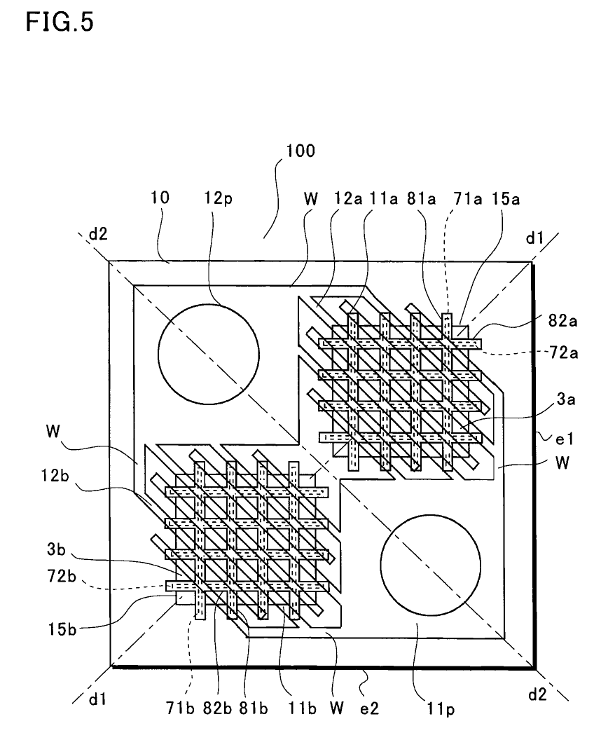

Next, with reference to FIGS. 4 and 5, a second embodiment of the present invention will be described.

In the second embodiment, a layout of first and second operation regions 15a and 15b and first and second pad electrodes 11p and 12p is the same as that in the first embodiment but a configuration of each of the first and second operation regions 15a and 15b is different from that in the first embodiment. Therefore, as to redundant points between the first and second embodiments, detailed description thereof will be omitted. Moreover, since the second operation region 15b has the same configuration as that of the first operation region 15a, the first operation region 15a will be described.

FIGS. 4A and 4B are plan views showing the first operation region 15a. FIG. 4A is a view in which an insulating film on a surface of a substrate and metal electrodes (a source electrode and a drain electrode) are omitted, and FIG. 4B is a view showing a state where the source and drain electrodes are disposed.

In the second embodiment, in addition to a gate region 71a extended along a first side e1 of a semiconductor substrate 10, another gate region 72a is provided, which is extended along a second side e2 extended in a direction different from that of the first side e1.

Specifically, the gate region 71a and the other gate region 72a are arranged in a lattice pattern so as to be perpendicular to each other. Note that a cross-sectional view along the line b-b in FIG. 4B is the same as that shown in FIG. 2B. When conductive layers 81a and 82a are provided, patterns thereof overlap with the gate regions 71a and 72a.

Moreover, source regions 5a and drain regions 6a are alternately arranged in an island pattern having a region defined by the gate region 71a and the other gate region 72a.

Furthermore, source electrodes 11a and drain electrodes 12a are arranged in a stripe pattern, respectively, in the first operation region 15a. The source electrodes 11a are extended in a direction along a second diagonal line d2 (see FIG. 5), for example, and connected to the plurality of source regions 5a, which are arranged while being spaced apart from each other in the second diagonal line d2 direction, through contact holes provided in an insulating film 9 covering the surface of the substrate. Moreover, the drain electrodes 12a are extended in the direction along the second diagonal line d2, for example, and connected to the plurality of drain regions 6a, which are arranged while being spaced apart from each other in the second diagonal line d2 direction, through contact holes provided in the insulating film 9 covering the surface of the substrate.

In the second embodiment, the first operation region 15a is a collective term for regions in which a channel region 3a, the source regions 5a, the drain regions 6a, the gate regions 71a and 72a and the source and drain electrodes 11a and 12a are provided. Moreover, the first operation region 15a has the same area as that of the channel region 3a.

Similarly, the second operation region 15b is a collective term for regions in which a channel region 3b, source regions 5b, drain regions 6b, gate regions 71b and 72b and source and drain electrodes 11b and 12b are provided. Moreover, the second operation region 15b has the same area as that of the channel region 3b.

FIG. 5 is a plan view showing a layout on the semiconductor substrate 10 in the second embodiment.

In the first operation region 15a, the source electrodes 11a and the drain electrodes 12a are formed in the stripe pattern extended in the second diagonal line d2 direction, for example, and are bundled by wirings W, respectively, outside the first operation region 15a so as to have a comb-teeth shape. The source electrodes 11a and the drain electrodes 12a are disposed in a state where the respective comb teeth are engaged with each other.

Similarly, in the second operation region 15b, the source electrodes 11b and the drain electrodes 12b are formed in the stripe pattern extended in the second diagonal line d2 direction, for example, and are bundled by wirings W, respectively, outside the second operation region 15b so as to have a comb-teeth shape. The source electrodes 11b and the drain electrodes 12b are disposed in a state where the respective comb teeth are engaged with each other.

The source electrodes 11a and 11b are connected to the first pad electrode (source pad electrode) 11p by the wirings W. The drain electrodes 12a and 12b are connected to the second pad electrode (drain pad electrode) 12p by the wirings W. Thus, the source pad electrode 11p is common-connected to the source regions 5a and 5b in the first and second operation regions 15a and 15b. Moreover, the drain pad electrode 12p is common-connected to the drain regions 6a and 6b in the first and second operation regions 15a and 15b.

The gate regions 71a and 72a are connected to a gate electrode (not shown) provided on a back surface of the p type semiconductor substrate 10 through the conductive layers 81a and 82a and the p type semiconductor substrate 10. Similarly, the gate regions 71b and 72b are connected to the gate electrode (not shown) provided on the back surface of the p type semiconductor substrate 10 through the conductive layers 81b and 82b and the p type semiconductor substrate 10.

Also in the second embodiment, the gate regions 71a and 71b in the first and second operation regions 15a and 15b are extended along the first side e1 of the semiconductor substrate 10. In the second embodiment, the other gate regions 72a and 72b in the first and second operation regions 15a and 15b are further provided along the second side e2 extended in the direction different from that of the first side e1.

The first and second operation regions 15a and 15b are disposed so as to be arranged in a step-like pattern along the first diagonal line d1 of the semiconductor substrate 10 as indicated by a dashed line. Specifically, the first and second operation regions 15a and 15b having the gate regions 71a and 71b extended along the first side e1 of the semiconductor substrate 10, respectively, are arranged along the first diagonal line d1. Alternatively, the first and second operation regions 15a and 15b having the other gate regions 72a and 72b extended along the second side e2 of the semiconductor substrate 10, respectively, are arranged along the first diagonal line d1.

Furthermore, the source pad electrode 11p and the drain pad electrode 12p are arranged along the second diagonal line d2 of the semiconductor substrate 10.

As described above, in this embodiment, both of the gate regions 71a and 71b in the two operation regions 15 are extended along the first side e1 of the semiconductor substrate 10 (or the other gate regions 72a and 72b are extended along the second side e2), and the source pad electrode 11p and the first operation region 15a are arranged along the first side e1. Moreover, along the second side e2 of the semiconductor substrate 10, the second side being extended in the direction different from that of the first side e1, the second operation region 15b and the source pad electrode 11p are arranged.

Accordingly, the space on the semiconductor substrate 10 can be effectively utilized. Thus, in the case where the same chip size as that in the conventional case is adopted, the areas of the first and second operation regions 15a and 15b can be increased. Moreover, the strain characteristics can be improved by increasing a current capacity.

Alternatively, by maintaining the areas of the two operation regions 15 to be the same as those in the conventional case, the chip size can be reduced to contribute to cost reduction by improvement in the wafer yield.

Note that, although not shown in the drawings, arrangement positions of the first and second operation regions 15a and 15b and those of the source and drain pad electrodes 11p and 12p may be replaced with each other, respectively. Furthermore, the respective pad electrodes 11p and 12p may be arranged along the first diagonal line d1 and the two operation regions 15 may be arranged along the second diagonal line d2.

Although the J-FET has been described above as an example, the embodiments of the present invention are not limited to the above. For example, the present invention is also applicable to a bipolar transistor. Specifically, although not shown in the drawings, the bipolar transistor includes: one conductivity type base regions provided in an opposite conductivity type semiconductor substrate to be a collector region; and an opposite type emitter regions provided in a stripe pattern in surfaces of the base regions.

In this case, the stripe-shaped base regions between the emitter regions are set as a pattern of the drain and source regions described above, and the emitter regions are set as a pattern of the gate regions. Moreover, base electrodes connected to the base regions are provided in the pattern of the drain electrodes (or the source electrodes), and emitter electrodes connected to the emitter regions are provided in the pattern of the source electrodes (or the drain electrodes). Moreover, the base electrodes and the emitter electrodes are disposed in a state where respective comb teeth are engaged with each other. Thus, first and second operation regions are formed.

In the bipolar transistor described above, the respective emitter regions (and the base regions) in the first and second operation regions are all extended along a first side of the semiconductor substrate. Moreover, the first and second operation regions are arranged along a first diagonal line of the semiconductor substrate. Furthermore, a base pad electrode connected to the base electrodes and an emitter pad electrode connected to the emitter electrodes are arranged along a second diagonal line of the semiconductor substrate.

Thus, a chip size can be reduced or areas of the operation regions can be increased.

As described above in detail, the following various effects can be achieved according to the present invention.

First, the chip size can be reduced while securing the same operation regions as those in the conventional case and also securing the safe pad size in the assembly step. More specifically, the chip size of 0.5 mm square can be reduced to 0.45 mm square. Thus, the yield of the chip can be improved to 1.25 times greater than that in the conventional structure.

Secondly, when the same chip size as that in the conventional structure is maintained, the areas of the operation regions can be increased while securing the safe pad size in the assembly step. Therefore, with the same gate width, the number of stripes of the gate regions can be increased. Thus, the current capacity can be increased. More specifically, the current capacity of 60 mA can be secured with the chip size of 0.45 mm square, for example. Compared with the conventional case where the current capacity is about 30 mA with the chip size of 0.5 mm square, reduction in the chip size and an increase in the current capacity can be realized.

Third, since the gate regions in the two operation regions can be maintained in the same direction, good strain characteristics can be achieved without deterioration.

Fourth, the operation regions and the pad electrodes can be arranged by utilizing the space on the chip. There has heretofore been adopted the configuration in which the pad electrodes are disposed on the operation regions with the insulating film interposed therebetween. However, there is a problem of occurrence of failures in wire bonding. Meanwhile, according to the present invention, it is possible to prevent deterioration of reliability due to failures in wire bonding even in a semiconductor device having a large current capacity.

What is claimed is:

1. A semiconductor device comprising:
a rectangular semiconductor substrate of a first general conductivity type;
a first operation region of a second general conductivity type formed in the rectangular substrate and comprising a plurality of linear impurity regions of the first general conductivity type formed in the first operation region;
a second operation region of the second general conductivity type formed in the rectangular substrate comprising a plurality of linear impurity regions of the first general conductivity type formed in the second operation region;
a first electrode pad disposed on the rectangular substrate and connected to the first operation region; and
a second electrode pad disposed on the rectangular substrate and connected to the second operation region,
wherein the linear impurity regions of the first and second operation regions are arranged parallel to an edge of the rectangular substrate,
the first and second operation regions are disposed along a first diagonal of the rectangular substrate so that the first diagonal intersects the first and second operation regions, and
the first and second electrode pads are disposed along a second diagonal of the rectangular substrate so that the second diagonal intersects the first and second electrode pads.

2. A semiconductor device comprising:
a rectangular semiconductor substrate of a first general conductivity type;
a first channel region of a second general conductivity type formed in the rectangular substrate and comprising a plurality of linear gate regions of the first general conductivity type, a plurality of source regions of the second general conductivity type and a plurality of drain regions of the second general conductivity type formed in the first channel region;
a second channel region of the second general conductivity type formed in the rectangular substrate and comprising a plurality of linear gate regions of the first general conductivity type, a plurality of source regions of the second general conductivity type and a plurality of drain regions of the second general conductivity type formed in the second channel region;
a source electrode pad disposed on the rectangular substrate and connected to the source regions of the first and second channel regions; and
a drain electrode pad disposed on the rectangular substrate and connected to the drain regions of the first and second channel regions,
wherein the linear gate regions of the first and second channel regions are arranged parallel to an edge of the rectangular substrate,
the first and second channel regions are disposed along a first diagonal of the rectangular substrate so that the first diagonal intersects the first and second channel regions, and
the source and drain electrode pads are disposed along a second diagonal of the rectangular substrate so that the second diagonal intersects the source and drain electrode pads.

3. The semiconductor device of claim 2, wherein the source and drain regions of the first and second channel regions are formed as stripes parallel to said edge of the rectangular substrate.

4. The semiconductor device of claim 2, further comprising a source electrode connected to the source regions of the first and second channel regions and extending in a direction parallel to said edge of the rectangular substrate, and a drain electrode connected to the drain regions of the first and second channel regions and extending in the direction parallel to said edge of the rectangular substrate.

5. The semiconductor device of claim 2, further comprising a plurality of another linear gate regions of the first general conductivity type formed in the first channel region and a plurality of another linear gate regions of the first general conductivity type formed in the second channel region, wherein the another linear gate regions of the first and second channel regions are parallel to another edge of the rectangular substrate that is normal to said edge of the rectangular substrate.

6. The semiconductor device of claim 5, wherein the source and drain regions are isolated from each other by the linear gate regions and the another linear gate regions.

7. The semiconductor device of claim 5, further comprising a source electrode connected to the source regions of the first and second channel regions and extending in a direction parallel to the second diagonal, and a drain electrode connected to the drain regions of the first and second channel regions and extending in the direction parallel to the second diagonal.

8. A semiconductor device comprising:
a rectangular semiconductor substrate of a first general conductivity type;
a first rectangular channel region of a second general conductivity type formed in the rectangular substrate and comprising a plurality of linear gate regions of the first general conductivity type, a plurality of source regions of the second general conductivity type and a plurality of drain regions of the second general conductivity type formed in the first rectangular channel region;
a second rectangular channel region of the second general conductivity type formed in the rectangular substrate and comprising a plurality of linear gate regions of the first general conductivity type, a plurality of source regions of the second general conductivity type and a plurality of drain regions of the second general conductivity type formed in the second rectangular channel region;
a source electrode pad disposed on the rectangular substrate and connected to the source regions of the first and second rectangular channel regions; and
a drain electrode pad disposed on the rectangular substrate and connected to the drain regions of the first and second rectangular channel regions,
wherein the linear gate regions of the first and second rectangular channel regions are arranged parallel to an edge of the rectangular substrate, and
a longitudinal edge of the first rectangular channel region overlaps partially with a longitudinal edge of the second rectangular channel region.
